(19) United States
(12) Patent Application Publication
(10) Pub. No.: US 2017/0343437 A1
(43) Pub. Date: Nov. 30, 2017

(54) PRESSURE SENSOR

(71) Applicant: DENSO CORPORATION, Kariya-city (JP)

(72) Inventor: Yasutake URA, Kariya-city (JP)

(21) Appl. No.: 15/603,652

(22) Filed: May 24, 2017

(30) Foreign Application Priority Data
May 27, 2016 (JP) 2016-106626

(51) Int. Cl. G01L 7/02; G01L 19/14

(52) U.S. Cl. CPC G01L 7/022; G01L 19/146; G01L 7/024; B81B 2201/0264

(57) ABSTRACT

A pressure sensor outputting an electrical signal upon a fluid pressure in a target space includes a diaphragm having a pressure receiving surface disposed in the target space for receiving a fluid pressure, and a back surface on a back side of the pressure receiving surface, an inner member disposed to face the back surface and a diaphragm supporting portion connected to the diaphragm. The diaphragm includes a center portion disposed to face the inner member and is distorted as a concave shape toward the detecting direction because of the heat transmitted to the pressure receiving surface and the distortion of the center portion as a concave shape toward the detecting direction. A contacting portion provided on a connecting portion between the center portion and the outside portion is in contact with the inner member.

### CROSS REFERENCE TO RELATED APPLICATION

This application is based on Japanese Patent Application No. 2016-106626 filed on May 27, 2016, the disclosure of which is incorporated herein by reference.

### FIELD

The present disclosure relates to a pressure sensor that detects a pressure of an object by transmitting the pressure from a diaphragm.

### BACKGROUND

A pressure sensor as shown in Japanese Patent No. 3993857 comprises a cylindrical sensor body, a diaphragm attached to a top portion of the sensor body, and a piezoelectric provided inside of the sensor body. In the pressure sensor, a charge in the piezoelectric is generated in accordance with a pressure applied to the diaphragm. The pressure is detected based on the charge.

An output error due to the thermal expansion of the diaphragm occurs when this kind of the pressure sensor is exposed to high temperature in use. The output error is referred to as a thermal distortion error hereinafter.

### SUMMARY

A pressure sensor outputting an electrical signal upon a fluid pressure in a target space includes a diaphragm having a pressure receiving surface disposed in the target space for receiving a fluid pressure, and a back surface on a back side of the pressure receiving surface, an inner member disposed to face the back surface and a diaphragm supporting portion connected to the diaphragm. The diaphragm includes a center portion disposed to face the inner member and is distorted as a concave shape toward the detecting direction because of the heat transmitted to the pressure receiving surface and the distortion of the center portion as a concave shape toward the detecting direction. A contacting portion provided on a connecting portion between the center portion and the outside portion is in contact with the inner member.

### BRIEF DESCRIPTION OF THE DRAWINGS

The above and other objects, features and advantages of the present disclosure will become more apparent from the following detailed description made with reference to the accompanying drawings.

In the drawings:

FIG. 1 is a diagram illustrating a cross-sectional view, showing an engine to which a pressure sensor is attached;

FIG. 2 is a diagram illustrating a cross-sectional view enlarging a main part of the pressure sensor;

FIG. 3 is a diagram illustrating a cross-sectional view enlarging a tip edge covered member of the top of the pressure sensor in FIG. 2;

FIG. 4 is a diagram illustrating a cross-sectional view showing a thermal distortion of the tip edge covered member in FIG. 3;

FIG. 5 is a diagram illustrating a cross-sectional view showing the tip edge covered member;

FIG. 6 is a diagram illustrating a cross-sectional view showing the tip edge covered member; and

FIG. 7 is a diagram illustrating a cross-sectional view showing a connecting rod.

### DETAILED DESCRIPTION

In the following, embodiments of the present disclosure are described with reference to the accompanying drawings. In the description which follows and in the drawings, identical or similar components bear the same reference numerals or characters.

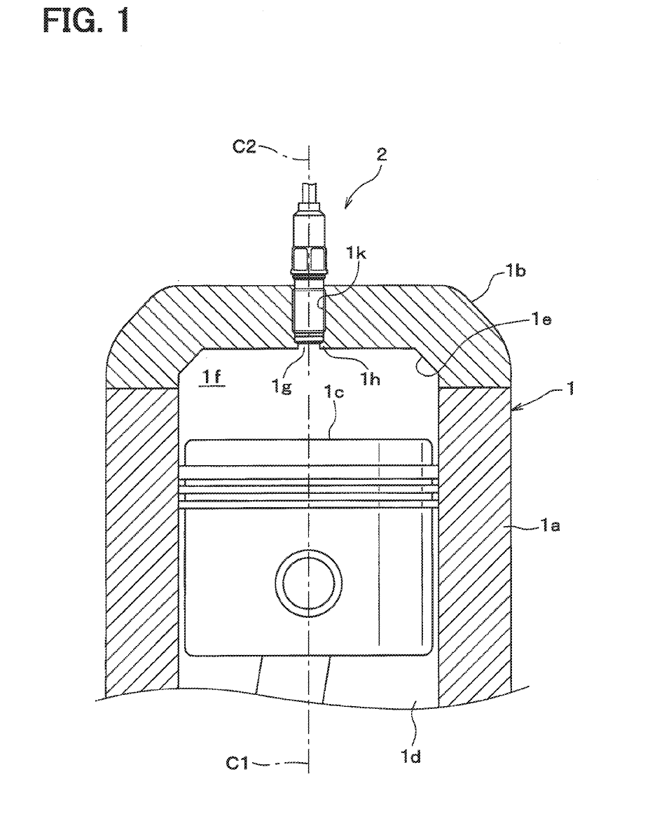

As shown in FIG. 1, an engine 1 as an internal combustion engine comprises a cylinder block 1a, a cylinder head 1b, and a piston 1c. The cylinder 1d is formed within the cylinder block 1a. The piston 1c is provided in the cylinder 1d such that the piston 1c reciprocates along a central axis line C1. The cylinder head 1b is fixed to the cylinder block 1a so as to cover an end of the piston 1c at the top dead center side in the cylinder 1d. A recess portion 1e is formed on the surface of the cylinder head 1b and the recess portion 1e is communicated with the cylinder 1d. A combustion chamber 1f is defined as a room between the piston 1c and the cylinder head 1b in the space surrounded by the cylinder 1d and the recess portion 1e.

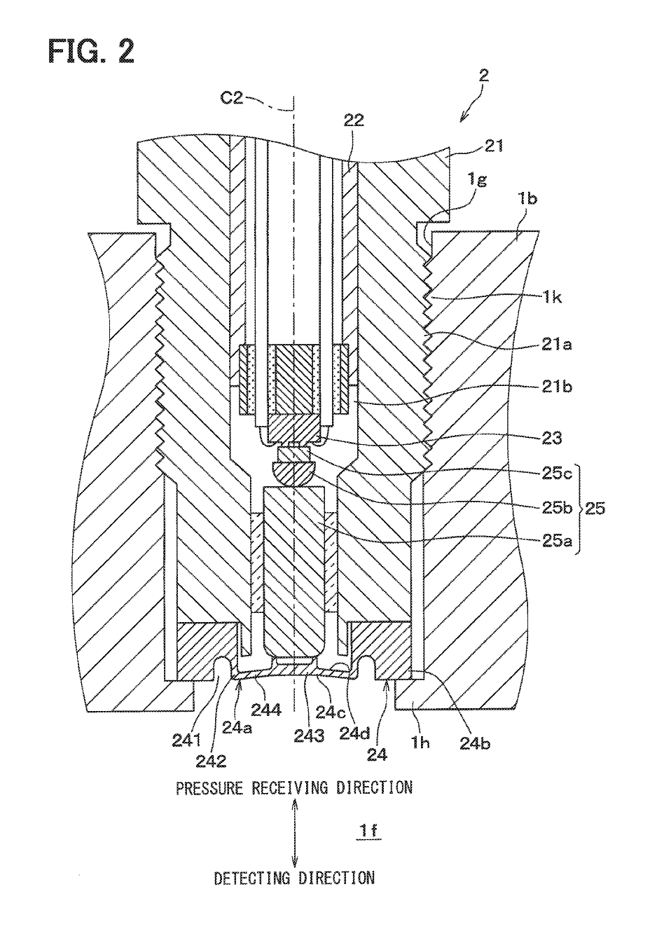

A sensor mounted hole 1g as a cylindrical-shaped through hole is formed in the cylinder head 1b. The sensor mounted hole 1g is formed to connect between the outer surface and the inner surface of the combustion chamber if. As shown in FIGS. 1 and 2, a flange portion 1h and a female threading 1k are provided on an inner surface of the sensor mounted hole 1g. The flange portion 1h protrudes toward the central axis line C1 from an end of the sensor mounted hole 1g, a position of which is on the side of the combustion chamber 1f. The female threading 1k is formed from the other side of the combustion chamber if (i.e. an opposite end of the sensor mounted hole 1g from the flange portion 1h) to the substantially central portion of the sensor mounted hole 1g along an axial direction of the sensor mounted hole 1g. The axial direction of the sensor mounted hole 1g is same as the direction along a direction of a central axial line C2. In the present embodiment, the central axis line C1 is not parallel to the central axis line C2 of the sensor mounted hole 1g.

The pressure sensor 2 in the embodiment outputs an electrical signal in response to a fluid pressure in the combustion chamber if. Here, the combustion chamber 1f is referred to as a target space. The pressure sensor 2 is referred to as an in-cylinder pressure sensor or a combustion pressure sensor. The pressure sensor 2 is attached to the cylinder head 1b through the sensor mounted hole 1g such that the pressure sensor 2 outputs an electrical signal on the basis of a combustion pressure of a fuel-air mixture.

A direction, which is parallel to the central axis line C2 of the sensor mounted hole 1g and which points from the combustion chamber if to the pressure sensor 2, is referred to as a pressure receiving direction (an upward direction as shown in FIG. 2). An opposite direction to the pressure receiving direction is referred to as a detecting direction (a downward direction as shown in FIG. 2). The detecting direction is the direction heading from the pressure sensor 2 to the combustion chamber if. The pressure sensor 2 has a longitudinal length, a direction of which is parallel to the central axis line C2 of the sensor mounted hole 1g. An edge of the pressure sensor 2 and its constituent parts positioned on the detecting direction side is referred to as a tip edge (a downward end in FIG. 2). On the other hand, an edge of the pressure sensor 2 and its constituent parts located in the pressure receiving direction is referred to as a base edge. The central axis line C2 of the sensor mounted hole 1g is identical to a central axis line of the pressure sensor 2 and its constituent parts. In the following explanation, the central axis line C2 shows a central axis line of the pressure sensor 2 and its constituent parts.

In shown in FIG. 2, the pressure sensor comprises a housing 21, an element supporting portion 22, a detecting element 23, a tip edge covered member 24, and a pressure transferring portion 25. The housing 21 is cylindrically formed. A male threading 21a engaged with the female threading 1k is formed on the tip portion in the outer surface of the housing 21. A housing hole 21b is formed inside of the housing 21 as a substantially cylindrical-shaped through hole, and the element supporting portion 22, the detecting element 23 and the pressure transferring portion 25 are housed within the housing hole 21b. The detecting element 23 is attached to the tip of the element supporting portion 22. In the embodiment, the detecting element 23 is piezoelectric and generates an electric charge in accordance with an applied pressure.

The tip edge covered member 24 covers the tip edge of the housing hole 21b. The tip edge covered member 24 is substantially cylindrical or substantially ring-shaped and axially symmetrical with respect to the central axis line C2. The tip edge covered member 24 comprises a diaphragm 24a and a diaphragm supporting portion 24b. In the embodiment, the tip edge covered member 24 is provided to face the combustion chamber 1f, so that the diaphragm 24a receives heat and the combustion pressure in accordance with combustion of the fuel-air mixture in the combustion chamber 1f.

The diaphragm 24a has a thin film-shape so as to deflect in the pressure receiving direction and in the detecting direction in accordance with the combustion pressure, and is formed as a circle shape (when viewed from a direction parallel to the central axis line C2). The pressure receiving surface 24c, which is a surface at the edge side of the diaphragm 24a, is provided to face the combustion chamber if in order to receive the heat and the combustion pressure. A back surface 24d of the pressure receiving surface 24c is a surface at the base edge side and is provided to face the pressure transferring portion 25. The diaphragm supporting portion 24b is formed as cylindrical-shape or circle-shape and surrounds the diaphragm 24a from the outside thereof. The diaphragm supporting portion 24b is connected to the diaphragm 24a for supporting thereof. The surface at the base edge side of the diaphragm supporting portion 24b is jointed to the edge surface of the housing 21. The pressure sensor 2 is equipped to the cylinder head 1b such that the surface at the edge side of the diaphragm supporting portion 24b is in contact with the flange portion 1h.

The pressure transferring portion 25 is provided between the detecting element 23 and the diaphragm 24a, so that the pressure applied to the diaphragm 24a is transferred to the detecting element 23. In the present embodiment, the pressure transferring portion 25 comprises a front rod 25a, a middle block 25b and a base edge block 25c in detail. A central axis line of the front rod 25a is identical to the central axis line C2. A front end of the front rod 25a faces the back surface 24d in order to be in contact with the diaphragm 24a. The middle block 25b is provided between the front rod 25a and the base edge block 25c. The middle block 25b is formed with substantially hemispherical shape and has a hemispherical surface as a front surface which contacts the base edge surface of the front rod 25a. A base edge surface of the base edge block 25c faces the detecting element 23 and contacts the detecting element 23.

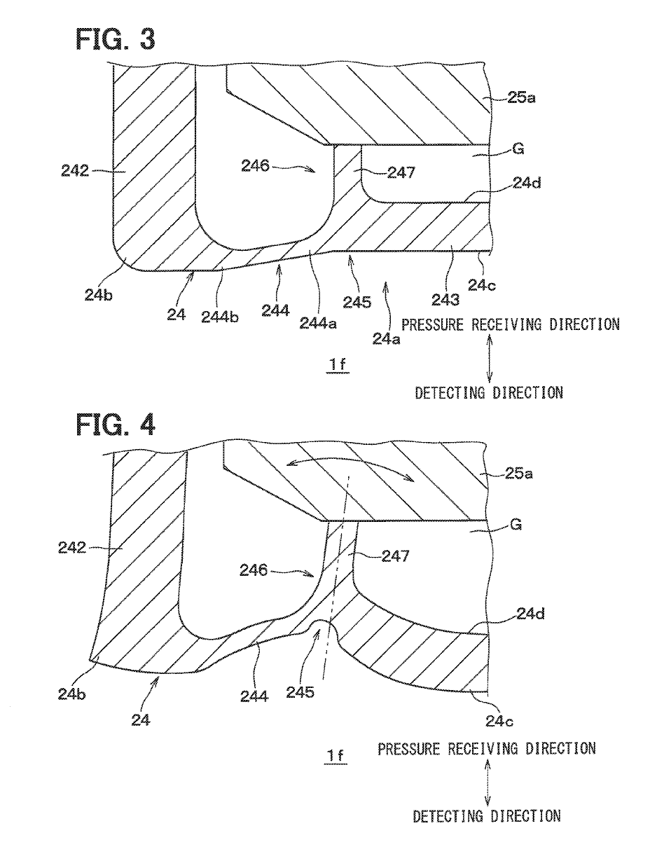

A configuration around the tip edge covered member 24 as the main portion of the pressure sensor 2 in the present embodiment is explained in detail by referring to FIG. 2 and FIG. 3.

The diaphragm supporting portion 24b has a groove 241 opening toward the detecting direction and is U-shaped in a cross-sectional view. The groove 241 is ring-shaped with a center of the central axis line C2 in a planar view. A side wall 242 is provided to be adjacent to the groove 241 of the diaphragm supporting portion 24b and to be positioned at a closer side of the central axis line C2 from the groove 241. The edge portion of the side wall 242 is connected to the diaphragm 24a. The side wall 242 is formed as a thin plate protruding toward the detecting direction and has a substantially cylindrical-shape with a central axis line which is identical to the central axis line C2. The side wall 242 is configured to bend toward a radial direction when the diaphragm experiences heat expansion toward the radial direction (namely, a left-right direction in FIG. 2) as a result of heat being received on the pressure receiving surface 24c.

The diaphragm 24a has a center portion 243 and an outside portion 244. The center portion 243 is a circular plate with a center on the central axis line C2. The center portion 243 faces the front rod 25a which corresponds to an inner member. The outside portion 244 is a ring-shape surrounding the center portion 243 from outside thereof, and is formed between the center portion 243 and the diaphragm supporting portion 24b. An inner edge 244a of the outside portion 244 is connected to the center portion 243. An outer edge 244b of the outside portion 244 is connected to the diaphragm supporting portion 24b.

In the present embodiment, the tip edge covered member 24 is provided to face the combustion chamber 1f such that the diaphragm 24a receives the combustion pressure in accordance with combustion of the fuel-air mixture in the combustion chamber if and such that the pressure receiving surface 24c is heated. The center portion 243 is heated by receiving the combustion pressure, and the center portion 243 is configured so that the amount of heat expansion at the pressure receiving surface 24c is much larger than the amount of heat expansion at the back surface 24d. The center portion 243 has a predetermined thickness in such a manner that, when the center portion 243 is heated by receiving the combustion pressure, the center portion 243 is bended as a convex shape toward the detecting direction by a predetermined temperature difference between parts of the center portion 243 adjacent to the pressure receiving surface 24c and parts of the center portion 243 adjacent to the back surface 24d.

The outside portion 244 is connected to both of the center portion 243 and the diaphragm supporting portion 24b in such a manner that the outside portion 244 is bended as a convex shape toward the pressure receiving direction by the heat transmitted to the pressure receiving surface 24c as well as by the bending of the center portion 243 as a convex shape toward the detecting direction. In the present embodiment, the center portion 243, the outside portion 244 and the diaphragm supporting portion 24b are seamlessly formed as one member by same material. The outside portion 244 is formed as a thin film, the thickness of which is much smaller than that of the center portion 243, so that the heat transmitted from the combustion pressure does not generate a substantial temperature difference between parts of the outside portion 244 adjacent to the pressure receiving surface 24c and parts of the outside portion 244 adjacent to the back surface 24d. So, a stiffness of the outside portion 244 is lower than that of the center portion 243. In other words, the center portion 243 is formed as a thicker portion of the diaphragm 24a. The outside portion 244 is formed as a thinner portion of the diaphragm 24a.

The outside portion 244 inclines relative to a standard plane in parallel to a normal line of the central axis line C2 in such a manner that the diaphragm 24a is formed as a recess shape facing the combustion chamber 1f when no pressure is applied to the diaphragm 24a. The inner edge 244a of the outside portion 244 is positioned on the pressure detecting direction side relative to the central axis line C2 in comparison with the position of the outer edge 244b of the outside portion 244.

A connecting portion 245 between the center portion 243 and the outside portion 244 has a contacting portion 246. In the present embodiment, the connecting portion 245 is a part of the center portion 243, and is an outer edge part of the center portion 243. The contacting portion 246 is a part of the diaphragm 24a for contacting the front rod 25a. The diaphragm 24a is provided to contact the front rod 25a only through the contacting portion 246. In the present embodiment, the contacting portion 246 has a diaphragm projection 247 protruding from the diaphragm 24a. The diaphragm projection 247 is a projection which protrudes at the connecting portion 245 toward the front rod 25a from the back surface 24d of the center portion 243. A gap G is formed between the back surface 24d of the center portion 243 and a front edge of the front rod 25a through the diaphragm projection 247. The dimensions of the gap G along a parallel direction to the central axis line C2 is corresponding to an amount of protruding from the back surface 24d to a top of the diaphragm projection 247 along a parallel direction to the central axis line C2.

In the present embodiment, the diaphragm projection 247 is formed with a substantially cylindrical shape, a central axis of which is identical to the central axis line C2. The diaphragm projection 247 is seamlessly formed as one member with the center portion 243 and the outside portion 244.

FIG. 4 shows a result calculated by a computer simulation regarding a thermal distortion of the tip edge covered member 24 shown in FIG. 3, when the tip edge covered member 24 receives heat by the combustion of the fuel-air mixture in the combustion chamber if. In the pressure sensor of the present embodiment, the pressure receiving surface 24c of the diaphragm 24a receives the combustion pressure and is heated by combustion of the fuel-air mixture in the combustion chamber 1f. The heat is momentary applied to the pressure receiving surface 24c and the center portion 243 has a predetermined thickness along the pressure receiving direction. So, by the heat transmitted to the pressure receiving surface 24c, a predetermined temperature difference at the center portion 243 along the thickness direction (namely, the pressure receiving direction) is generated. The center portion 243 is deformed as a concave shape toward the detecting direction (see FIG. 4).

The thickness of the outside portion 244 is quite thinner than that of the center portion 243. So, a temperature difference at the outside portion 244 along the thickness direction is less in comparison with the center portion 243, when the heat is momentary transmitted to the pressure receiving surface 24c as described in the last paragraph. The outside portion 244 is integrally connected to the diaphragm supporting portion 24b though the outer edge 244b. Accordingly, the outside portion 244 is deformed as a concave shape toward the pressure receiving direction (see FIG. 4).

The connecting portion 245 is a portion for connecting the center portion 243 which is deformed as a concave shape toward the detecting direction to the outside portion 244 which is deformed as a concave shape toward the pressure receiving direction. A displacement of the connecting portion 245 along the detecting direction or the pressure receiving direction due to the heat transmitted to the pressure receiving surface 24c should be suppressed. The displacement of the connecting portion 245 along the detecting direction or the pressure receiving direction is 0 (zero) at some position, even if the heat is transmitted to the pressure receiving surface 24c (see two-dot-one-dash line in FIG. 4). By providing the contacting portion 246 at such position, a displacement of the contacting portion 246 along the detecting direction or the pressure receiving direction before due to the heat transmitted to the pressure receiving surface 24c is also suppressed. A state of a displacement at an end part of the diaphragm projection 247 in the connecting portion 245 in the pressure receiving direction side because of the transmitted heat is a rotating state about the connecting portion 245. Namely, the displacement, along the detecting direction or the pressure receiving direction, of the end part of the diaphragm projection 247 in the pressure receiving direction side is suppressed. Accordingly, in the present embodiment it is possible to reduce thermal distortion error.

As described above, the connecting portion 245 has a part with 0 displacement along the detecting direction or the pressure receiving direction as a result of the transmitted heat. In order to realize such a configuration, as mentioned above, the center portion 243 is bended as a convex shape toward the detecting direction and the outside portion 244 is bended as a convex shape toward the pressure receiving direction. The configuration can be realized by considering appropriately a balance of a heat deformation state of each portion and a stiffness of each portion, without excessively reducing the thickness of the outside portion 244. Accordingly, in such configuration, it is possible to maintain strength of the diaphragm 24a and the diaphragm supporting portion 24b.

In the present embodiment, the diaphragm 24a and the front rod 25a are connected to each other through only the contacting portion 246. In detail, the gap G is provided between the center portion 243 of the diaphragm 24a and the front rod 25a and is identical to a protrusion amount of the diaphragm projection 247. So, even if the center portion 243 of the diaphragm 24a is expanded toward a direction along the central axis line C2 because of heat, a bias to the front rod 25a from the center portion 243 because of the expansion can be suppressed. In addition, it is possible to reduce thermal distortion error.

The diaphragm 24a is expanded toward a radial direction (namely, a left-right direction in the figures) due to the heat transmitted to the pressure receiving surface 24c. In the present embodiment, in accordance with the thermal expansion, an end of the side wall 242 is bended outwardly. The bending of the side wall 242 because of the thermal expansion toward a radial direction of the diaphragm 24a suppresses the displacement of the diaphragm 24a along the detecting direction or the pressure receiving direction well. In addition, it is possible to reduce thermal distortion error.

### Other Embodiments

The present disclosure is not limited to the above mentioned embodiments and various design changes can be made. Some primary changes are explained later. In the following embodiments, only design changes are explained. As long as the specific explanation is not described, in the other embodiments, the configuration with the same reference number in the other embodiments is applied to same explanation in the above mentioned embodiments, as long as the explanation is not inconsistency.

In the present disclosure, the pressure sensor is not limited to a piezoelectric type. The present disclosure apply to other type of the pressure sensor (for example, electrostatic capacity type) differing from the piezoelectric type.

The central axis line C1 and the central axis line C2 of the sensor mounted hole 1g (the central axis line C2 of the pressure sensor 2) may be in parallel. In such configuration, the central axis line C1 and the central axis line C2 may not coincide as well. The groove 241 may not be necessary. The connecting portion 245 may be a part of the center portion 243, a part of the outside portion 244 or a portion extending over both of the center portion 243 and the outside portion 244.

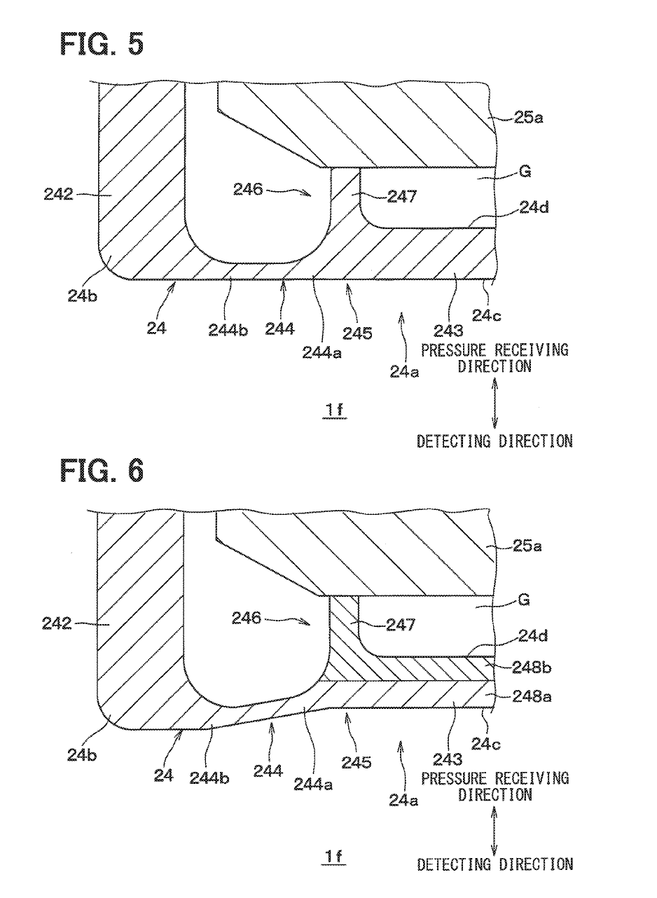

As shown in FIG. 5, the outside portion 244 may be parallel to the standard plane in parallel to a normal line of the central axis line C2. Namely, the outside portion 244 may be formed in such a manner that the inner edge 244a of the outside portion 244 and the outer edge 244b of the outside portion 244 are located at the same position toward a direction parallel to the central axis line C2.

In the cylindrical-shaped diaphragm projection 247 extending along a parallel to the central axis line C2, a plurality of slits may be so formed that the slits penetrate into the diaphragm projection 247 in a radial direction. The configuration of the diaphragm projection 247 is not limited to a cylindrical-shape. The configuration of the diaphragm projection 247 may be a circular cylinder-shape, a core-shape, a polygon-shape, or a polygonal cone-shape. The configuration of the diaphragm projection 247 may be separated into several small projections at a predetermined interval which are positioned at a circumference with the central axis line C2 as a center.

As shown in FIG. 6, the center portion 243 may comprise a large expansion layer 248a and a small expansion layer 248b as a bimetal construction. The large expansion layer 248a is located on a side of the pressure receiving surface 24c. The large expansion layer 248a is seamlessly and integrally formed with the outside portion 244 by the same material. The small expansion layer 248b is formed by a material which has a lower coefficient of thermal expansion than a coefficient of thermal expansion of the large expansion layer 248a, and is located on a side of the back surface 24d. The small expansion layer 248b is seamlessly and integrally formed with the diaphragm projection 247 by the same material.

In the above configuration, the thickness of the center portion 243 may be equal to that of the outside portion 244. The thickness of the center portion 243 may be larger than that of the outside portion 244. Since the thickness of the center portion 243 is larger than that of the outside portion 244, the strength of the diaphragm 24a and the diaphragm supporting portion 24b can be maintained. The configuration having the large expansion layer 248a and the small large expansion layer 248b may be realized by means other than adhesives.

The configuration of the pressure transferring portion 25 is not limited to the present embodiment. For example, the middle block 25b and the base edge block 25c may be integrally formed. The base edge block may be eliminated.

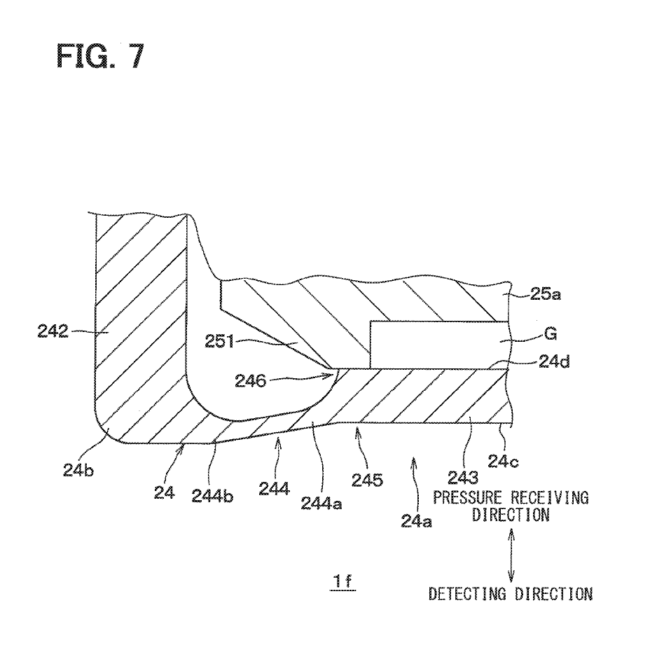

As shown in FIG. 7, an inner projection 251 may be provided on the front rod 25a on a side of the pressure transferring portion 25 instead of the diaphragm projection 247 formed on the contacting portion 246. The inner projection 251 is formed to extend from the pressure transferring portion 25 to the contacting portion 246. In this case, the gap G is provided between the back surface 24d of the center portion 243 and a front edge of the front rod 25a which is positioned inside of the inner projection 251.

The direction extending from the pressure receiving surface 24c to the back surface 24d on the diaphragm 24a is equivalent to the pressure receiving direction. Namely, the pressure receiving direction and the detecting direction are defined as a direction parallel to thickness direction of the diaphragm 24a.

Although a plurality of parts and portions are seamlessly and integrally formed by same material in the above explanation, such parts and portions may be formed by fixing the parts and portions each other. In a same manner, although a plurality of parts and portions are formed by fixing the parts and portions each other in the above explanation, such parts and portions may be seamlessly and integrally formed by same material.

Although a plurality of parts and portions may be formed by same material in the above explanation, such parts and portions are formed by different material. In a same manner, although a plurality of parts and portions are formed by different material in the above explanation, such parts and portions may be formed by same material.

The other embodiments are not limited to the above explanation. A plurality of the embodiments may be combined. All or part of the above embodiment may be combined with all or part of the other embodiments. Namely, the front rod 25a as shown in FIG. 3 may be replaced by the front rod 25a having the inner projection 251 as shown in FIG. 7.

The present disclosure is not limited to an in-cylinder pressure sensor. However, the pressure sensor in the present disclosure is most effective for the in-cylinder pressure sensor, because the center portion 243 deforms like bi-metal because of the instant heat by applying the pressure to the diaphragm 24a.

What is claimed is:

1. A pressure sensor outputting an electrical signal based upon a fluid pressure in a target space, comprising:
a diaphragm having
a pressure receiving surface disposed to face said target space so as to receive said fluid pressure, and
a back surface on a back side of said pressure receiving surface, said diaphragm being distorted along a pressure receiving direction from said pressure receiving surface to said back surface or along a detecting direction opposite to said detecting direction upon being applied with said fluid pressure;
an inner member disposed to face said back surface; and
a diaphragm supporting portion connected to said diaphragm to support said diaphragm, said diaphragm supporting portion having a cylindrical shape to surround said diaphragm,
wherein said diaphragm comprises
a center portion disposed to face said inner member and configured to distort as a concave shape toward said detecting direction in accordance with a heat transmitted to said pressure receiving surface;
an outside portion disposed between said center portion and said diaphragm supporting portion, the outside portion being connected to said center portion and said diaphragm supporting portion in such a manner that said outside portion is distorted as a concave shape toward said pressure receiving direction in accordance with said heat transmitted to said pressure receiving surface and said distortion of said center portion as a concave shape toward said detecting direction; and
a contacting portion provided on a connecting portion between said center portion and said outside portion so as to be in contact with said inner member.

2. The pressure sensor according to claim 1, wherein said diaphragm and said inner member are configured so as to be connected to each other through only said connecting portion.

3. The pressure sensor according to claim 2, wherein
said contacting portion has a diaphragm projection extending from said back surface to said inner member at said connecting portion, and
a gap is formed between said inner member and said back surface of said center portion through said diaphragm projection.

4. The pressure sensor according to claim 2, wherein
said inner member has an inner projection extending to said contacting portion of said diaphragm, and
a gap is formed between said back surface of said center portion and said inner member through said inner projection.

5. The pressure sensor according to claim 1, wherein
said center portion and said outside portion are seamlessly and integrally formed, and
a thickness of said outside portion is thinner than that of said center portion.

6. The pressure sensor according to claim 1, wherein
said outside portion has
an inner edge connected to said center portion, and
an outer edge connected to said diaphragm supporting portion, and
an inner edge position being a position of said inner edge toward a direction parallel to a central axis line of said diaphragm supporting portion is identical to an outer edge position being a position of said outer edge toward said direction, or said inner edge position is located at a position closer on a side of said pressure receiving direction from said outer edge position.

7. The pressure sensor according to claim 1, wherein
said target space is a combustion chamber of an internal combustion engine, and
said fluid pressure is a combustion pressure of a fuel-air mixture in said combustion chamber.

8. The pressure sensor according to claim 7, wherein said center portion is configured such that an amount of thermal expansion in said pressure receiving surface is larger than that in said back surface because of heat transmitted to said pressure receiving surface by combustion of said fuel-air mixture.
